(19) United States
(12) Patent Application Publication
(10) Pub. No.: US 2013/0161784 A1
(43) Pub. Date: Jun. 27, 2013

(54) SEMICONDUCTOR PACKAGE

(71) Applicant: SAMSUNG ELECTRONICS CO., LTD., Suwon-Si (KR)

(72) Inventors: Chul-yong Jang, Hwaseong-si (KR); Young-lyong Kim, Gunpo-si (KR)

(73) Assignee: SAMSUNG ELECTRONICS CO., LTD., Suwon-si (KR)

(21) Appl. No.: 13/651,465

(22) Filed: Oct. 15, 2012

(30) Foreign Application Priority Data
Dec. 23, 2011 (KR) 10-2011-0141709

(51) Int. Cl. H01L 29/02

(52) U.S. Cl. 257/528; 257/E29.002

(57) ABSTRACT

A semiconductor package includes a substrate; first and second pads that are disposed separate from each other on the substrate; and a solder resist that allows a portion of the substrate in a region between the first and second pads and to be exposed while covering a portion of the first and second pads in a region other than the region between the first and second pads.

### CROSS-REFERENCE TO RELATED APPLICATIONS

This application claims the benefit of Korean Patent Application No. 10-2011-0141709, filed on Dec. 23, 2011, in the Korean Intellectual Property Office, the disclosure of which is incorporated herein in its entirety by reference.

### BACKGROUND

The inventive concept relates to a semiconductor package, and more particularly, to a semiconductor package in which passive devices may be mounted with high reliability.

Recently, electronic devices have become smaller and increasingly more lightweight, with the electronic devices having multiple functions and providing high performance. Accordingly, there is an increasing demand for a semiconductor package formed by mounting various electronic components on one substrate. In particular, in a case of a semiconductor package in which a passive device and an active device are mounted, a reliability of the semiconductor package depends on the shapes of a pad and a solder resist on which the passive device is mounted. Thus, it may be desirable to provide a semiconductor package having a structure in which a passive device may be stably mounted, and a process error may be minimized.

### SUMMARY

According to an aspect of the inventive concept, a semiconductor package includes a substrate. The package further includes first and second pads that are disposed separate from each other on the substrate. A solder resist exposes a portion of the substrate in a region between the first and second pads and covers a portion of the first and second pads in a region other than the region between the first and second pads.

According to another aspect of the inventive concept, a semiconductor package includes first and second pads disposed separate from each other on a substrate. The package also includes a device electrically connected to the first and second pads. In addition, a solder resist is formed on the substrate between the first and second pads.

According to another aspect of the inventive concept, a semiconductor package includes a substrate having a first portion and a second portion. An active device is formed in the first portion and a passive device is further formed in the second portion. The passive device includes first and second pads disposed separate from each other on the second portion of the substrate. In the passive device, a solder resist is formed on the substrate between the first and second pads and on a portion of each of the first and second pads. The package further includes a molding member covering the active device and the passive device. In addition, a connection terminal is formed on a bottom surface of the substrate so as to be electrically connected to an external apparatus.

Various other aspects and embodiments are within the contemplation of the inventive concepts and will be apparent to those skilled in the art based on this disclosure. The inventive concepts are therefore not limited to those specific aspects and embodiments disclosed herein.

### BRIEF DESCRIPTION OF THE DRAWINGS

Exemplary embodiments of the inventive concepts will be more clearly understood from the following detailed description taken in conjunction with the accompanying drawings in which:

FIG. 1 is a somewhat schematic plan view of a semiconductor package according to certain embodiments of the inventive concepts;

FIG. 2 is a somewhat schematic plan view illustrating a semiconductor package of a region in which a passive device of FIG. 1 is mounted according to one embodiment of the inventive concepts;

FIG. 3 is a somewhat schematic cross-sectional view illustrating the semiconductor package of FIG. 2, taken along a line I-I′ of FIG. 2;

FIG. 4 is a somewhat schematic plan view illustrating a semiconductor package of a region in which a passive device is mounted according to another embodiment of the inventive concepts;

FIG. 5 is a somewhat schematic plan view illustrating a semiconductor package of a region in which a passive device is mounted according to yet another embodiment of the inventive concepts;

FIG. 6 is a somewhat schematic plan view illustrating a semiconductor package of a region in which a passive device is mounted according to a further embodiment of the inventive concepts;

FIG. 7 is a somewhat schematic plan view illustrating a semiconductor package of a region in which a passive device is mounted according to a still further embodiment of the inventive concepts;

FIG. 8 is a somewhat schematic plan view illustrating a semiconductor package in which a passive device is mounted according to an additional embodiment of the inventive concepts;

FIG. 9 is a somewhat schematic cross-sectional view illustrating the semiconductor package of FIG. 8, taken along a line II-II′ of FIG. 8;

FIG. 10 is a somewhat schematic cross-sectional view illustrating a semiconductor package in which passive devices and an active device are mounted on a substrate according to another embodiment of the inventive concepts;

FIG. 11 is a somewhat schematic cross-sectional view illustrating a semiconductor package in which passive devices and an active device are mounted on a substrate according to still another embodiment of the inventive concepts;

FIG. 12 is a somewhat schematic cross-sectional view illustrating a semiconductor package in which passive devices and an active device are mounted on a top surface of a substrate, and a passive device is mounted on a bottom surface of the substrate according to a further embodiment of the inventive concepts;

FIG. 13 is a somewhat schematic cross-sectional view illustrating a semiconductor package according to a tenth embodiment of the inventive concept;

FIGS. 14 through 19 are somewhat schematic cross-sectional views of a method of manufacturing a semiconductor package including the passive device of FIG. 9, according to yet further embodiments of the inventive concepts;

FIG. 20 is a somewhat schematic diagram illustrating a system according to another embodiment of the inventive concepts; and

FIG. 21 is a somewhat schematic perspective view illustrating an electronic device in which one or more of the semiconductor packages according to one or more embodiments of the inventive concepts may be implemented.

### DETAILED DESCRIPTION OF THE EMBODIMENTS

The present inventive concepts will now be described more fully with reference to the accompanying drawings, in which various exemplary embodiments of the inventive concepts are shown. The inventive concepts may, however, be embodied in many different forms and should not be construed as being limited to the embodiments set forth herein. Rather, these embodiments are provided so that this disclosure will be thorough and complete, and will fully convey the inventive concepts to those of ordinary skill in the art.

With respect to the drawings, shapes in the drawings may be revised according to desired manufacturing technologies and/or tolerances. Therefore, the attached drawings illustrating exemplary embodiments of the inventive concepts are referred to in order to gain a sufficient understanding of the inventive concept, the merits thereof, and the objectives accomplished by the implementation of the inventive concept but are not to scale or limiting with respect to shapes, sizes, or the like. Like reference numerals denote like elements. Furthermore, in the drawings, the thicknesses of layers and regions are exaggerated for clarity.

It will be understood that when an element or layer is referred to as being “on” another element or layer, the element or layer can be directly on another element or layer or there may be intervening elements or layers. Also, the term “and/or” includes any and all combinations of one or more of the associated listed items.

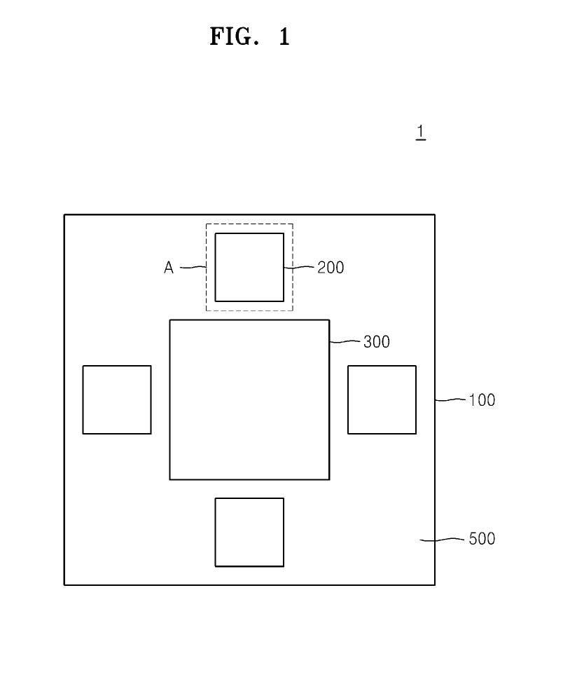

FIG. 1 is a somewhat schematic plan view of a semiconductor package 1 according to certain embodiments of the inventive concepts.

Referring to FIG. 1, the semiconductor package 1 may include a substrate 100, and an active device 300 and a passive device 200 that are mounted on the substrate 100.

Also, the semiconductor package 1 may further include a molding member 500. The molding member 500 may be formed to cover a top surface of the substrate 100, as well as side surfaces and top surfaces of the passive device 200 and the active device 300.

The substrate 100 may include a metal pattern (not shown) and a via (not shown) for providing an interlayer connection. Here, the metal pattern (not shown) may have a single-layered structure or a multi-layered structure. For example, the substrate 100 may be a printed circuit board (PCB), a flexible PCB (FPCB), a tape substrate, or the like.

Also, a plurality of pads that are electrically connected to the metal pattern (not shown) may be formed on the top surface of the substrate 100.

Also, a contact pad (not shown) that is electrically connected to the plurality of pads may be formed on a bottom surface of the substrate 100. The contact pad may be electrically connected to an external apparatus (not shown) via a connection terminal (also not shown). The external apparatus may be a main board or the like but examples of the external apparatus are not limited thereto. The active device 300 and the passive device 200 that are mounted on the substrate 100 may thereby be electrically connected to the external apparatus.

The active device 300 may be a chip device that actively uses a non-linear portion. For example, the active device 300 may be a semiconductor chip but examples of the active device 300 are not limited thereto.

The passive device 200 may comprise a chip device that is linear, or if the passive device 200 has a non-linear portion, the passive device 200 does not use the non-linear portion.

For example, the passive device 200 may be a capacitor, a resistor, an inductor, or the like, but the passive device 200 is not limited thereto. The passive device 200 may increase a signal processing speed of the active device 300 or may perform a filtering function.

The passive device 200 may be mounted with the active device 300. For example, a pad pattern used to mount the passive device 200 on the substrate 100 may be broadly divided into two types: (1) a solder mask defined (SMD) type; and (2) a non-solder mask defined (NSMD) type. In the SMD type, the pad pattern is defined by a solder resist, and in the NSMD type, the pad pattern is not defined by a solder resist.

According to a structure of the pad pattern used to mount the passive device 200 around the active device 300, a characteristic of the semiconductor package 1 may be improved, and a yield rate of production of the semiconductor package 1 may be improved.

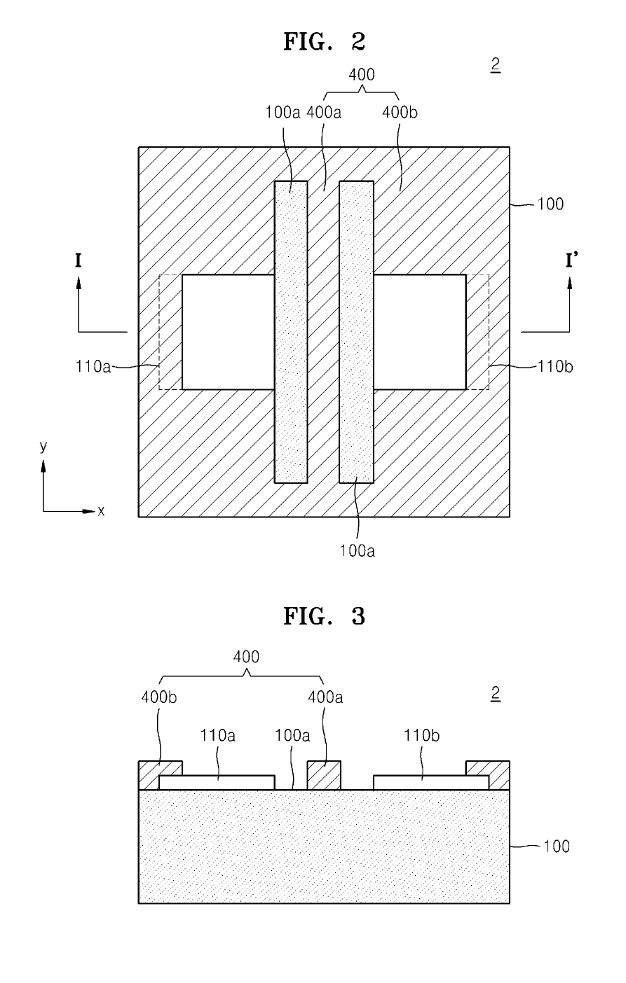

Hereinafter, with reference to FIG. 2, a description of a structure of the semiconductor package 1 in which the passive device 200 may be stably mounted so as to increase reliability of the semiconductor package 1 will be provided.

FIG. 2 is a somewhat schematic plan view illustrating a semiconductor package 2 of a region A in which the passive device 200 of FIG. 1 is mounted according to one embodiment of the inventive concepts. FIG. 3 is a somewhat schematic cross-sectional view illustrating the semiconductor package 2 of FIG. 2, taken along a line I-I′ of FIG. 2.

Referring to FIGS. 2 and 3, a first pad 110a and a second pad 110b that are electrically connected to a circuit layer (not shown) of the substrate 100, and are separated from each other, may be disposed on the top surface of the substrate 100, where a passive device (not shown) is mounted on the first and second pads 110a and 110b. Although the first and second pads 110a and 110b disposed on the top surface of the substrate 100 are illustrated as having a quadrangular shape, a shape of the first and second pads 110a and 110b is not limited thereto.

In order to expose predetermined portions of a solder resist 400 and the substrate 100, the top surface of the substrate 100 may further include open regions 100a in addition to a region in which the first and second pads 110a and 110b are disposed.

The solder resist 400 may include a first solder resist 400a and a second solder resist 400b. The first solder resist 400a may be disposed at a position on the substrate 100 which is distant (or spaced away) from an edge of each of the first and second pads 110a and 110b by a predetermined distance. Also, the first solder resist 400a may be disposed between the first and second pads 110a and 110b. In this regard, the first and second pads 110a and 110b may be substantially symmetrically disposed about the first solder resist 400a.

Because the semiconductor package 2 includes the first solder resist 400a, when the passive device (not shown) is mounted on the first and second pads 110a and 110b, it is possible to prevent a filling material (not shown) from flowing to the first and second pads 110a and 110b. The filling material (not shown) may include a conductive material that may be used in a reflow process.

Accordingly, the first solder resist 400a may function as a barrier to prevent the passive device (not shown) from being short-circuited by the filling material (not shown).

Also, the open regions 100a may be formed at both sides of the first solder resist 400a so as to expose side surfaces of the first and second pads 110a and 110b and a portion of the substrate 100.

The second solder resist 400b may be formed on the top surface of the substrate 100 so as to expose predetermined regions of the first and second pads 110a and 110b. That is, the second solder resist 400b may be formed to cover side surfaces of the first and second pads 110a and 110b while top surfaces of the first and second pads 110a and 110b are exposed.

Because the predetermined regions of the first and second pads 110a and 110b are exposed, the top surfaces of the first and second pads 110a and 110b may be surrounded by the second solder resist 400b and thus may have a step-shaped relationship with respect to the second solder resist 400b. Also, side surfaces of the first and second pads 110a and 110b can be exposed by the open regions 100a, and thus may have a step-shaped relationship with respect to the substrate 100.

Thus, in a surface-mount technology (SMT) process in which the passive device (not shown) is mounted on the first and second pads 110a and 110b, the filling material (not shown) that is supported by the second solder resist 400b having the step-shaped relationship with respect to the first and second pads 110a and 110b may flow to the open regions 100a. It is therefore possible to prevent the filling material (not shown) from flowing to a top surface of the second solder resist 400b.

Because the open regions 100a are formed in a y direction, a molding member (not shown) may easily fill a space between the substrate 100 and the passive device (not shown) mounted on the first and second pads 110a and 110b.

Thus, due to the molding member (not shown) formed in the space between the substrate 100 and the passive device (not shown), a cavity between the open regions 100a and a bottom surface of the passive device (not shown) may be easily removed. Also, a bonding energy between the molding member (not shown) and the substrate 100 is stronger than a bonding energy between the molding member (not shown) and the solder resist 400, so that structural reliability of the semiconductor package 2 with the aforementioned structure may be improved.

A contact pad (not shown) may also be disposed on the bottom surface of the substrate 100 so as to be electrically connected to the first and second pads 110a and 110b. The contact pad (not shown) may be electrically connected to an external apparatus such as a main board.

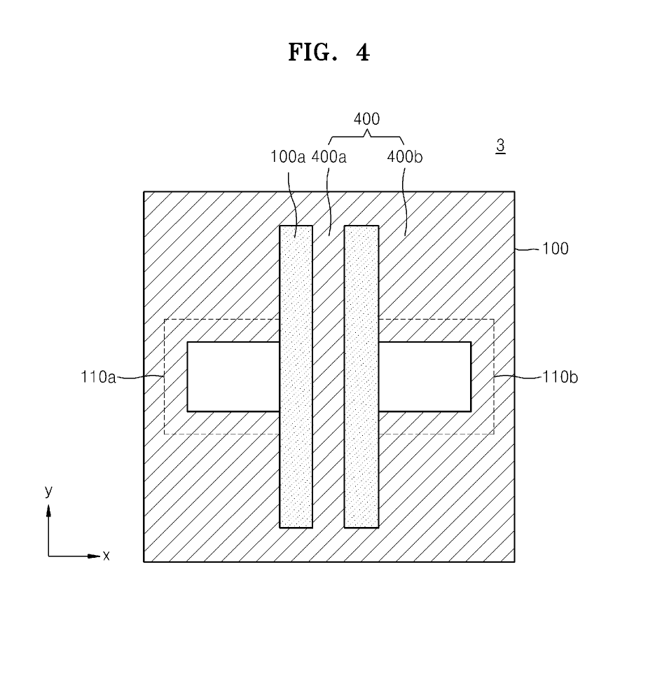

FIG. 4 is a somewhat schematic plan view illustrating a semiconductor package 3 of a region in which a passive device is mounted according to a further embodiment of the inventive concepts.

Referring to FIG. 4, unlike the semiconductor package 2 of FIG. 2, in the semiconductor package 3, side surfaces of the first and second pads 110a and 110b may be covered by the second solder resist 400b in certain regions, while other side surface regions of the first and second pads 110a and 110b are exposed by the open regions 100a.

Top surface areas of the first and second pads 110a and 110b which are exposed may be determined in consideration of a size of the passive device (not shown) mounted on the first and second pads 110a and 110b, or an amount of a filling material used to mount the passive device (not shown) on the first and second pads 110a and 110b.

That is, a size of the passive device (not shown) that is mounted on the semiconductor package 3 of FIG. 4 may be less than a size of the passive device (not shown) that is mounted on the semiconductor package 2 of FIG. 2. Or, when a lesser amount of a filling material is used in a reflow process of mounting the passive device (not shown), the semiconductor package 3 of FIG. 4 may be used.

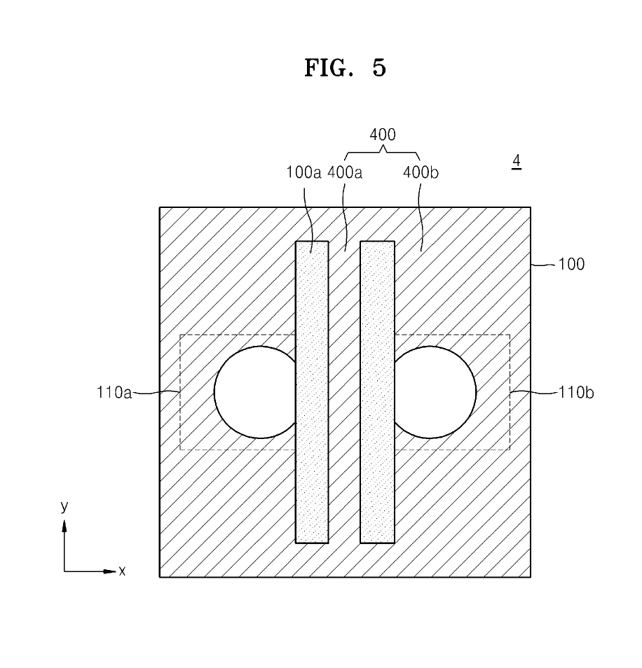

FIG. 5 is a somewhat schematic plan view illustrating a semiconductor package 4 of a region in which a passive device is mounted according to a still further embodiment of the inventive concepts.

Referring to FIG. 5, unlike the semiconductor package 2 of FIG. 2, in the semiconductor package 4, side surface areas of the first and second pads 110a and 110b may be covered by the second solder resist 400b, while other side surface areas of the first and second pads 110a and 110b may be exposed by the open regions 100a.

Also, in the embodiments of FIGS. 2 and 4, top surface areas of the first and second pads 110a and 110b which are exposed may have a quadrangular shape. In the embodiment illustrated in FIG. 5, however, the exposed top surface areas of the first and second pads 110a and 110b may have a substantially round shape. The shape of the exposed top surface areas of the first and second pads 110a and 110b is not limited to being a substantially round shape, and may, for example, be a triangular shape, a polygonal shape, or any other desired shape.

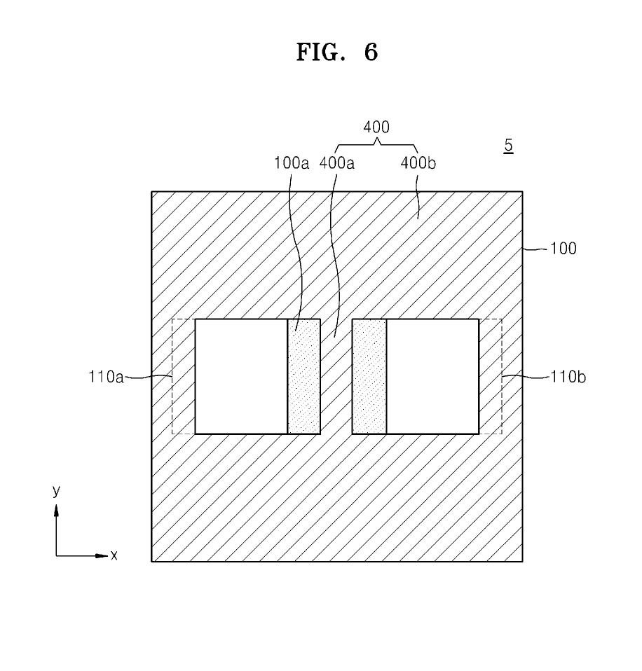

FIG. 6 is a somewhat schematic plan view illustrating a semiconductor package 5 of a region in which a passive device is mounted according to yet another embodiment of the inventive concepts.

Referring to FIG. 6, unlike the semiconductor package 2 of FIG. 2, a length (in a y direction) of the open regions 100a in the semiconductor package 5 may be the same as a length (in the y direction) of side surfaces of the first and second pads 110a and 110b which are exposed through the second solder resist 400b.

However, the length of the open regions 100a is not limited thereto and thus, according to the length (in the y direction) of the first and second pads 110a and 110b exposed by the second solder resist 400b, and a size (in the y direction) of the passive device (not shown) mounted on the exposed first and second pads 110a and 110b, the length of the open regions 100a may be smaller or greater than a width (in the y direction) of the exposed first and second pads 110a and 110b.

That is, when the length (in the y direction) of the exposed first and second pads 110a and 110b is greater than the size (in the y direction) of the passive device (not shown), the length (in the y direction) of the open regions 100a may be smaller than the length (in the y direction) of the exposed first and second pads 110a and 110b, and may be greater than the size (in the y direction) of the passive device (not shown).

When a molding process is not performed on the first and second pads 110a and 110b, a molding member is not required to flow to a space between the substrate 100 and the passive device (not shown) mounted on the first and second pads 110a and 110b. In this case, the length (in the y direction) of the open regions 100a may be smaller than the length (in the y direction) of the first and second pads 110a and 110b.

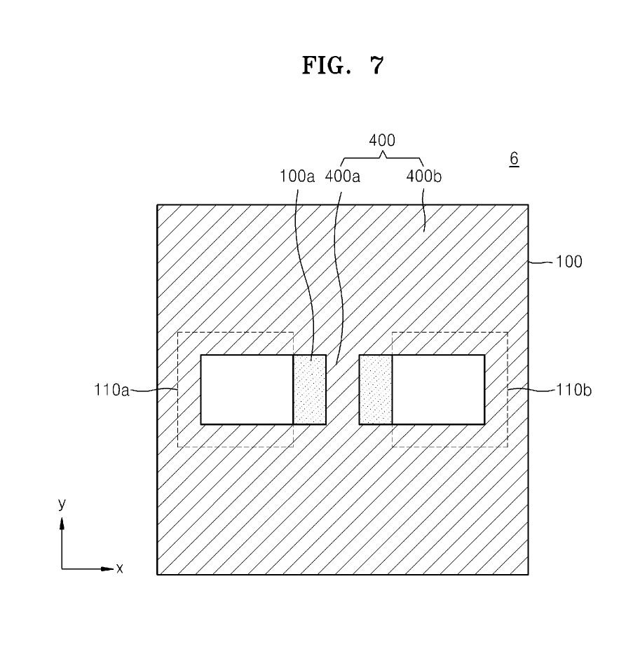

FIG. 7 is a somewhat schematic plan view illustrating a semiconductor package 6 of a region in which a passive device is mounted according to an additional embodiment of the inventive concepts.

Referring to FIG. 7, a size of an area of the first and second pads 110a and 110b that are exposed by the second solder resist 400b in the semiconductor package 6 may be smaller than a size of an area of the first and second pads 110a and 110b that are exposed by the second solder resist 400b in the semiconductor package 2 of FIG. 2.

Also, side surfaces of the first and second pads 110a and 110b may be exposed so that a length (in a y direction) of the open regions 100a that form a step-shaped relationship with respect to the substrate 100 may be the same as a length (in the y direction) of the first and second pads 110a and 110b. That is, depending on a length (in the y direction) of the passive device (not shown) mounted on the first and second pads 110a and 110b, the length (in the y direction) of the first and second pads 110a and 110b exposed by the second solder resist 400b, and the length (in the y direction) of the open regions 100a may be substantially equal to each other or may be different from each other.

For example, when the length (in the y direction) of the exposed first and second pads 110a and 110b is greater than a size (in the y direction) of the passive device (not shown), the length (in the y direction) of the open regions 100a may be smaller than the length (in the y direction) of the first and second pads 110a and 110b and may be substantially equal to or greater than the size (in the y direction) of the passive device (not shown).

Also, when a molding process is not performed on the first and second pads 110a and 110b, a molding member is not required to flow to a space between the substrate 100 and the passive device (not shown) mounted on the first and second pads 110a and 110b, so that the length (in the y direction) of the open regions 100a may be smaller than the length (in the y direction) of the first and second pads 110a and 110b.

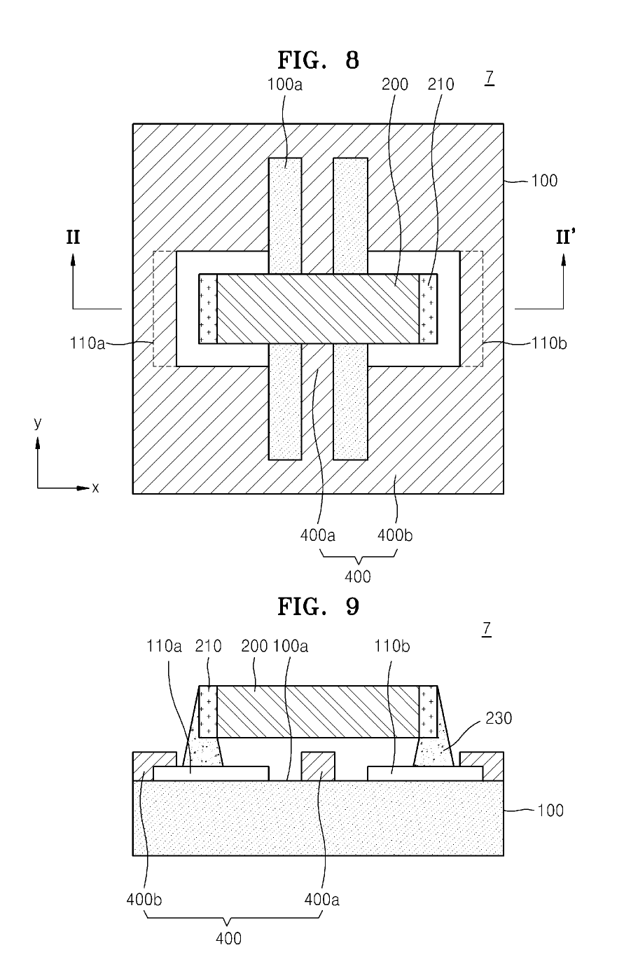

FIG. 8 is a somewhat schematic plan view illustrating a semiconductor package 7 in which a passive device 200 is mounted according to a yet further embodiment of the inventive concepts. FIG. 9 is a somewhat schematic cross-sectional view illustrating the semiconductor package 7 of FIG. 8, taken along a line II-II′ of FIG. 8.

Referring to FIGS. 8 and 9, the semiconductor package 7 may include a substrate 100, first and second pads 110a and 110b formed on the substrate 100, a passive device 200 mounted on the first and second pads 110a and 110b, a first solder resist 400a that is separated from the first and second pads 110a and 110b (with the first solder resist 400a being formed between the first and second pads 110a and 110b), and a second solder resist 400b formed on the substrate 100 so as to expose portions of the first and second pads 110a and 110b. The semiconductor package 7 may further include a filling material 230 to electrically connect the passive device 200 and the first and second pads 110a and 110b. The filling material 230 may include a conductive material that may be used in a reflow process.

An electrode 210 of the passive device 200 may be electrically connected to the first and second pads 110a and 110b via the filling material 230. For example, the passive device 200 may be a capacitor, a resistor, an inductor, or the like. When the passive device 200 is a capacitor, the electrode 210 may include Cu/Ni/Sn. Also, when the passive device 200 is a resistor, the electrode 210 may include Ag/Ni/Sn.

Because the passive device 200 is mounted on the first and second pads 110a and 110b, and the filling material 230 is disposed on the first and second pads 110a and 110b, three surfaces of which are surrounded by the second solder resist 400b, the semiconductor package 7 may facilitate a rework process. That is, when an error occurs in the passive device 200 during a test process, a reflow process can be performed, wherein the filling material 230 is melted so that the passive device 200 may be easily separated from the substrate 100, and another passive device 200 may be newly mounted thereon.

Also, because the semiconductor package 7 includes a first solder resist 400a that is separated from the first and second pads 110a and 110b and is formed between the first and second pads 110a and 110b, as the filling material 230 flows from the first pad 110a to the second pad 110b in the reflow process for electrically connecting the passive device 200 and the first and second pads 110a and 110b, it is possible to prevent the passive device 200 from being short-circuited by the filling material 230.

Also, because the passive device 200 is mounted on the first and second pads 110a and 110b via an SMT process, and open regions 100a are arranged to expose portions of the substrate 100, when a molding process is performed, a molding member (not shown) may easily fill a space between the substrate 100 and the passive device 200 via the open regions 100a.

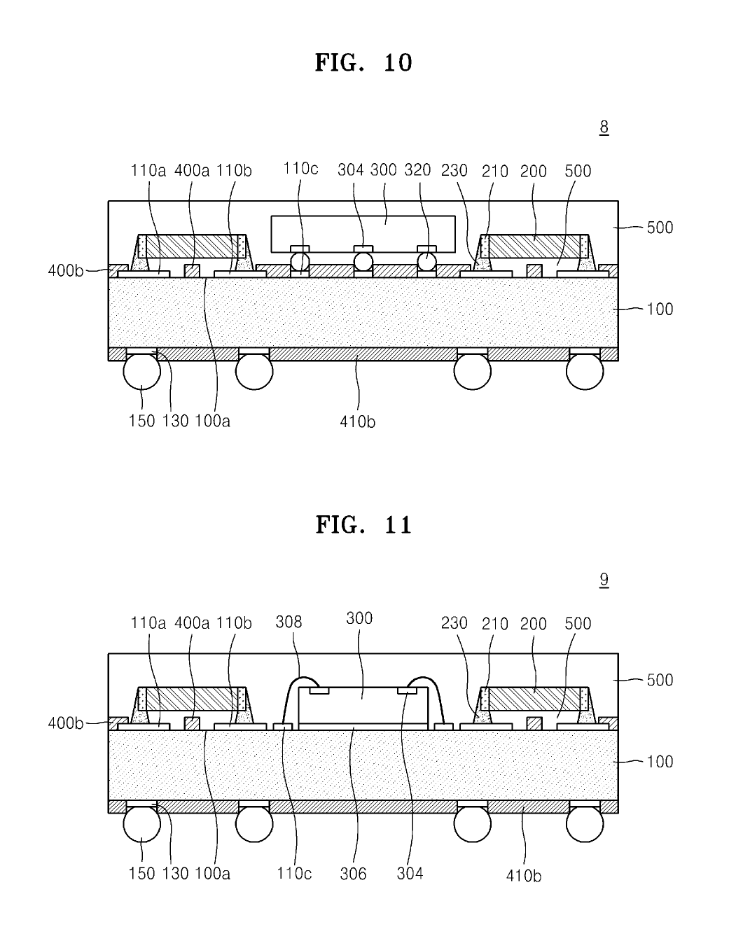

FIG. 10 is a somewhat schematic cross-sectional view illustrating a semiconductor package 8 in which passive devices 200 and an active device 300 are mounted on a substrate 100 according to a additional embodiment of the inventive concepts.

Referring to FIG. 10, the semiconductor package 8 may include the substrate 100, as well as the passive devices 200 and the active device 300 that are mounted on a top surface of the substrate 100. The substrate 100 may, for example, be a PCB, an FPCB, a tape substrate, or the like. On the top surface of the substrate 100, first and second pads 110a and 110b may be formed which are electrically connected to the passive devices 200, and third pads 110c that are electrically connected to the active device 300 may also be formed.

Each passive device 200 mounted on the first and second pads 110a and 110b may be a capacitor, a resistor, an inductor, or the like. Also, the passive devices 200 mounted on the first and second pads 110a and 110b may be the same type or different types of passive devices.

Also, at least one active device 300 may be mounted on the substrate 100. For example, the active device 300 may be a transistor, a semiconductor chip, or the like, but the active device 300 is not limited to these examples. Hereinafter, it is assumed that the active device 300 is a semiconductor chip.

The semiconductor chip 300 may include an integrated circuit (IC). For example, the IC may include a memory circuit or a logic circuit. Also, the semiconductor chip 300 may be a memory chip or a non-memory chip. For example, the semiconductor chip 300 may include a controller, a flash memory, a phase-change random access memory (PRAM), a resistive random-access memory (RRAM), a ferroelectric random-access memory (FeRAM), a dynamic random-access memory (DRAM), or other device.

A plurality of pads 304 connected to the IC may be formed on an active surface of the semiconductor chip 300. The pads 304 may be formed of a metal material including, for instance, aluminium (Al), copper (Cu), silver (Ag), gold (Au), palladium (Pd), etc.

The semiconductor chip 300 may be electrically connected to the third pads 110c via a flip-chip bonding process. That is, the semiconductor chip 300 may electrically connect the pads 304, which are formed on the active surface, to the third pads 110c formed on the substrate 100, using connecting members 320. The connecting members 320 may, for instance, be conductive bumps such as solder balls, pins, lead lines, or the like. The solder balls may, for example, be formed of lead (Pb), tin (Sn), an alloy of Pb and Sn, silver (Ag), copper (Cu), aluminium (Al), or the like, by using a soldering device, but the solder balls are not limited to these examples.

According to the embodiment of FIG. 10, only one semiconductor chip 300 is mounted on the substrate 100, but a plurality of semiconductor chips 300 may be mounted on the substrate 100. In a case where a plurality of semiconductor chips 300 are mounted on the substrate 100, the semiconductor chips 300 may be the same type or different types of semiconductor chips.

A structure of the top surface of the substrate 100, on which the passive devices 200 are mounted, can be the same as with respect to the descriptions provided above with reference to FIGS. 2 through 9, and thus, detailed descriptions thereof are omitted here.

A plurality of fourth pads 130 may be formed on a bottom surface of the substrate 100 to electrically connect a third solder resist 410b and the substrate 100 to connection terminals 150. The connection terminals 150 may be conductive bumps such as solder balls, pins, lead lines, or the like. The solder balls may be formed of lead (Pb), tin (Sn), an alloy of Pb and Sn, silver (Ag), copper (Cu), aluminium (Al), or the like, by using a soldering device, but are not limited thereto.

The semiconductor package 8 may further include a molding member 500. The molding member 500 may be formed to cover the top surface of the substrate 100, side surfaces and top surfaces of the passive devices 200 and the semiconductor chips 300. The molding member 500 may be formed of a synthetic resin material including an epoxy resin, a curing agent, organic/inorganic filling materials, and the like and may be injection-molded in a mold. The molding member 500 may be formed of a polymer material such as a resin. For example, the molding member 500 may be formed of an epoxy molding compound (EMC). Because the open regions 100a are formed in both sides of the first solder resist 400a between the first and second pads 110a and 110b, a molding process may be easily performed in a space between the passive devices 200 and the substrate 100 via the open regions 100a.

Thus, the passive devices 200 may be stably mounted on the substrate 100 due to the open regions 100a, and electrical defects of the passive devices 200 may be more reliably prevented due to the first solder resist 400a. Reliability of the semiconductor package 8 may therefore also be increased.

FIG. 11 is a somewhat schematic cross-sectional view illustrating a semiconductor package 9 in which passive devices 200 and an active device 300 are mounted on a substrate 100 according to another embodiment of the inventive concepts. Referring to FIG. 11, in the semiconductor package 9, the active device 300 (i.e., a semiconductor chip 300) may be mounted in the substrate 100 via a bonding layer 306.

In this embodiment, a non-active surface of the semiconductor chip 300 faces the substrate 100, and the semiconductor chip 300 is mounted on the substrate 100 via the bonding layer 306. Also, a plurality of pads 304 formed on an active surface of the semiconductor chip 300 may be electrically connected to a plurality of third pads 110c via connecting members 308. For example, the connecting members 308 may be bonding wires, or the like.

According to the embodiment of FIG. 11, only one semiconductor chip 300 is mounted on the substrate 100, but a plurality of semiconductor chips 300 may be mounted on the substrate 100. In a case where a plurality of semiconductor chips 300 are mounted on the substrate 100, the semiconductor chips 300 may be the same type or different types of semiconductor chips.

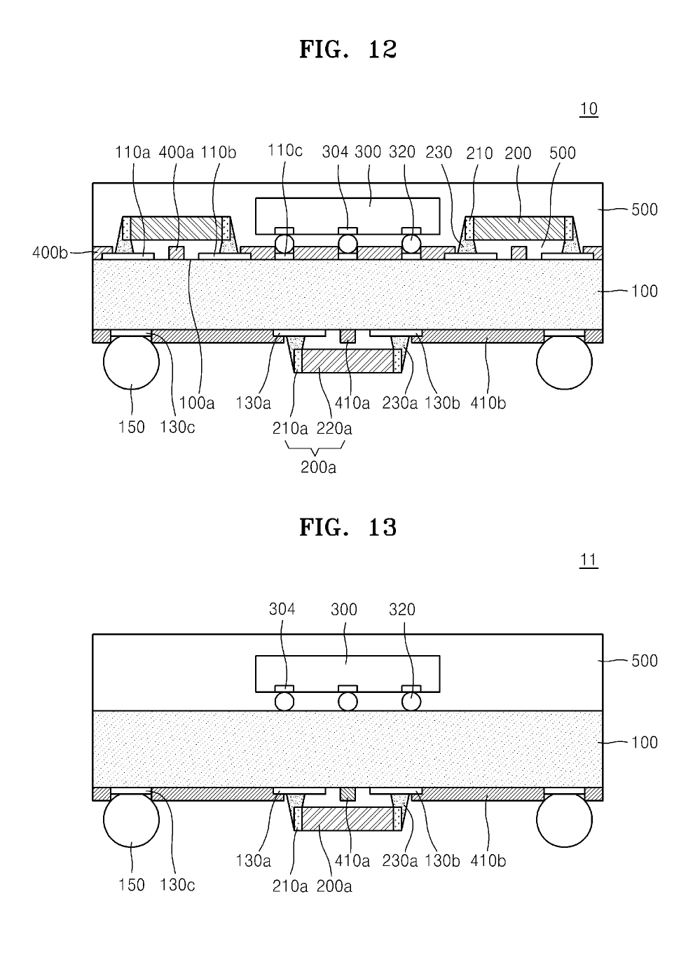

FIG. 12 is a somewhat schematic cross-sectional view illustrating a semiconductor package 10 in which passive devices 200 and an active device 300 are mounted on a top surface of a substrate 100, and a passive device 200a is mounted on a bottom surface of the substrate 100 according to yet another embodiment of the inventive concepts.

Referring to FIG. 12, unlike the semiconductor package 8 of FIG. 10, the semiconductor package 10 may further include a passive device 200a mounted on the bottom surface of the substrate 100. In this present embodiment, only one passive device 200a is mounted on the bottom surface of the substrate 100, but the inventive concepts are not limited thereto. A plurality of passive devices 200a may be mounted on the bottom surface of the substrate 100.

A structure of the bottom surface of the substrate 100, on which the passive device 200a is mounted, can be the same as a structure of the top surface of the substrate 100 which is described above with reference to FIGS. 2 through 9, and thus, additional detailed descriptions thereof are omitted.

The semiconductor package 10 may further include a molding member (not shown) that covers the passive device 200a mounted on the bottom surface of the substrate 100. A thickness of the molding member (not shown) may be less than a thickness of a connection terminal 150 formed on a fourth pad 130c of the substrate 100.

The molding member (not shown) may be formed of a synthetic resin material including an epoxy resin, a curing agent, organic/inorganic filling materials, and the like and may be injection-molded in a mold. The molding member (not shown) may be formed of a polymer material such as a resin (e.g., the molding member (not shown) may be formed of an EMC).

FIG. 13 is a somewhat schematic cross-sectional view illustrating a semiconductor package 11 according to yet another embodiment of the present inventive concepts. Referring to FIG. 13, the semiconductor package 11 may include a substrate 100, a semiconductor chip 300 mounted on a top surface of the substrate 100, and a passive device 200a mounted on a bottom surface of the substrate 100.

According to the present embodiment, only one semiconductor chip 300 is mounted on the top surface of the substrate 100, but the inventive concepts are not limited thereto. A plurality of semiconductor chips 300 may be stacked. For example, a plurality of semiconductor chips 300 may be formed in a manner such that a through silicon via (not shown) is formed in the plurality of semiconductor chips 300 that are mounted on the substrate 100 using a flip-chip method. However, the inventive concepts are not limited thereto and the plurality of semiconductor chips 300 may alternatively be mounted using a bonding wire method or other desired method on the top surface of the substrate 100.

According to the present embodiment, only one passive device 200a is mounted on the bottom surface of the substrate 100, but the inventive concepts are not limited thereto. A plurality of passive devices 200a may be mounted on the bottom surface of the substrate 100.

The semiconductor package 11 may further include a molding member 500. The molding member 500 may be formed to cover the top surface of the substrate 100, and side and top surfaces of the semiconductor chip 300. The molding member 500 may be formed of a synthetic resin material including an epoxy resin, a curing agent, organic/inorganic filling materials, and the like and may be injection-molded in a mold. The molding member 500 may be formed of a polymer material such as a resin (e.g., the molding member 500 may be formed of an EMC).

Also, the semiconductor package 11 may further include a molding member (not shown) that covers side and bottom surfaces of the passive device 200a mounted on the bottom surface of the substrate 100.

FIGS. 14 through 19 are somewhat schematic cross-sectional views illustrating a method of manufacturing a semiconductor package including the passive device 200 of FIG. 9, according to another aspect of the inventive concepts.

Referring to FIG. 14, a substrate 100 is provided. The substrate 100 may be a PCB, an FPCB, a tape substrate, or the like. On a top surface of the substrate 100, first and second pads 110a and 110b may be formed to be electrically connected to the passive devices 200 (see FIG. 18).

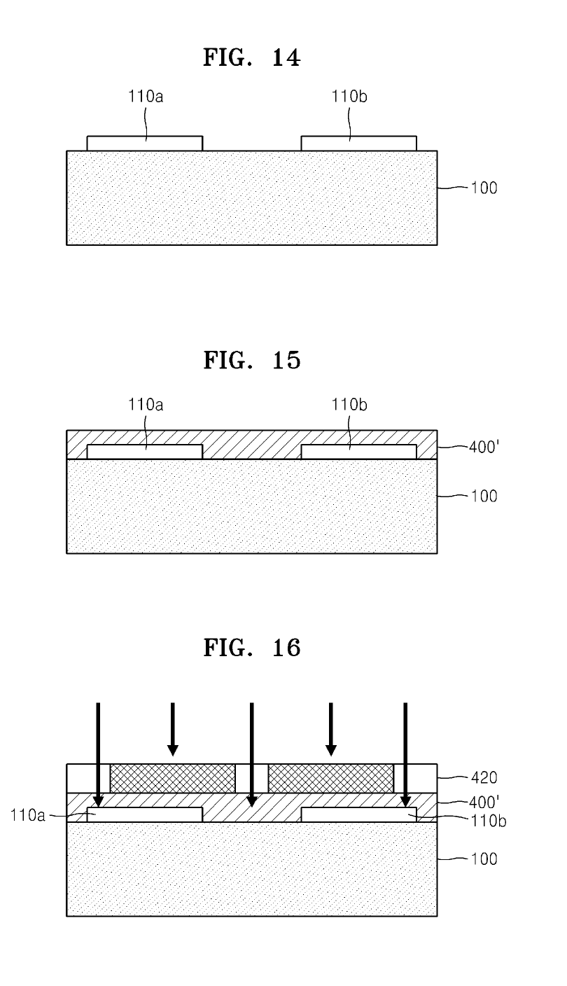

Next, referring to FIG. 15, a solder resist layer 400′ is formed to cover the substrate 100, and the first and second pads 110a and 110b. The solder resist layer 400′ may be formed of a heat-resistant coated material, and it is possible to expose predetermined regions of the first and second pads 110a and 110b by processing the solder resist layer 400′. The solder resist layer 400′ may, for instance, be formed by using a screen printing method, a roller coating method, a curtain coating method, or a spray coating method, for example.

Next, referring to FIG. 16, a master film 420 having a predetermined pattern formed thereon can be bonded on the solder resist layer 400′. The master film 420 has a pattern by which an ultraviolet ray passes through a portion of solder resist layer 400′ that is to be removed, and the ultraviolet ray does not pass through a portion of the solder resist layer 400′ that is to be maintained.

Next, an exposure process can be performed on the master film 420 by using the ultraviolet ray, so that the solder resist layer 400′ is cured. When curing by the ultraviolet ray is not sufficiently performed, the solder resist layer 400′ may become loose in following processes, so the exposure process should be performed to sufficiently cure the solder resist layer 400′. Here, the master film 420 on portions of the first and second pads 110a and 110b may be patterned to substantially prevent the ultraviolet ray from passing therethrough, so that the master film 420 on the blocked portions is not cured.

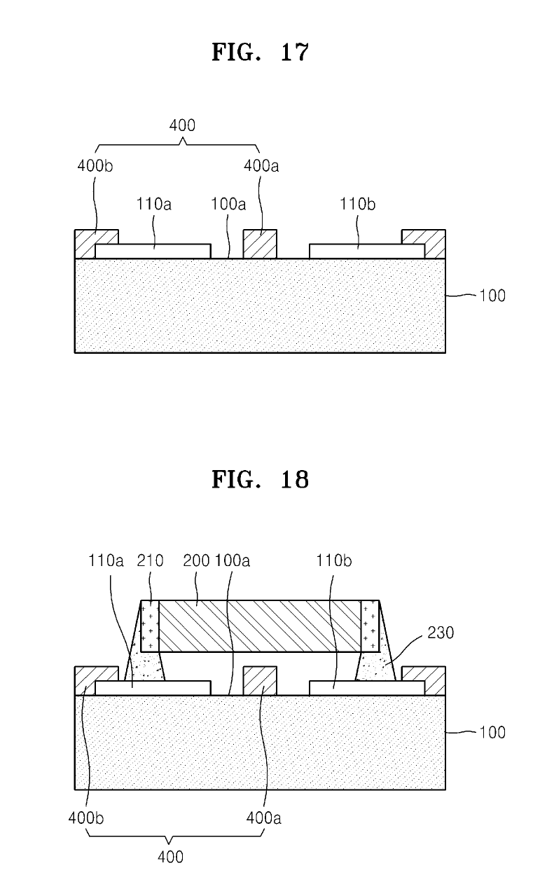

Next, referring to FIGS. 16 and 17, the master film 420 is removed, and a developing process is performed on the solder resist layer 400′, so that the portions of the first and second pads 110a and 110b may be exposed, and open regions 100a that expose the substrate 100 may be formed. That is, by performing the developing and exposure processes, side surfaces of the first and second pads 110a and 110b may be exposed and may have a step-shaped relationship with respect to the open regions 100a. Three side surfaces of the first and second pads 110a and 110b may be surrounded by a second solder resist 400b. Also, a first solder resist 400a may be formed between the first and second pads 110a and 110b with a predetermined distance therebetween.

Next, referring to FIG. 18, the passive device 200 may be mounted on the first and second pads 110a and 110b via an SMT process. An electrode 210 of the passive device 200 may be electrically connected to the first and second pads 110a and 110b via a filling material 230. The filling material 230 may include a conductive material that may be used in a reflow process. For example, the passive device 200 may be a capacitor, a resistor, an inductor, or the like, but the passive device 200 is not limited to these examples. When the passive device 200 is a capacitor, the electrode 210 may include Cu/Ni/Sn. Also, when the passive device 200 is a resistor, the electrode 210 may include Ag/Ni/Sn.

Because one or more side surfaces of the first and second pads 110a and 110b are surrounded by the second solder resist 400b, it is possible to prevent the filling material 230 from flowing to the second solder resist 400b. Thus, when an error occurs in the passive device 200, a rework process may be easily performed. That is, when an error occurs in the passive device 200 in a test process, if a reflow process is performed, the filling material 230 is melted, so that the passive device 200 may be easily separated from the substrate 100, and another passive device 200 may be newly mounted thereon.

Also, in the semiconductor package, the first solder resist 400a (which is separated from each of the first and second pads 110a and 110b and has a predetermined distance between the first and second pads 110a and 110b) functions as a filling material barrier, so that it is possible to prevent an occurrence of a short-circuit which would occur if the filling material 230 were permitted to flow from the first pad 110a to the second pad 110b during the reflow process for electrically connecting the passive device 200 and the first and second pads 110a and 110b.

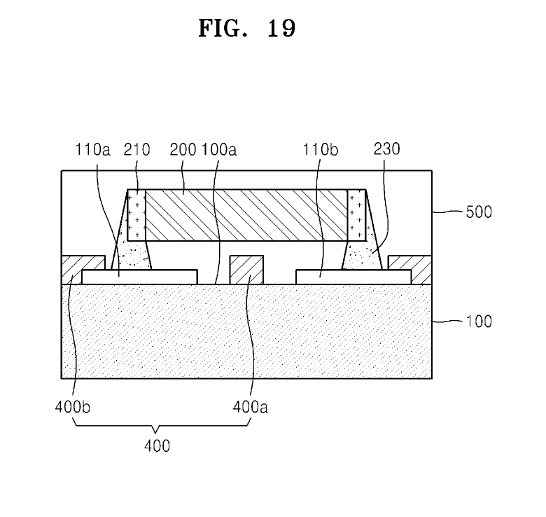

Next, referring to FIG. 19, a molding process may be performed by using a molding member 500 to cover the top surface of the substrate 100 and side and top surfaces of the passive device 200. The molding member 500 may be formed of the same material such as a synthetic resin material as in the previous embodiments. Because the open regions 100a are formed with respect to the first solder resist 400a between the first and second pads 110a and 110b on which the passive device 200 is mounted, the molding process may be easily performed in a space between the passive device 200 and the substrate 100. Thus, the passive device 200 may be stably mounted on the substrate 100, so that a reliability of the semiconductor package may be increased.

Next, connection terminals (not shown) for electrical connection with an external apparatus (not shown) may be formed on a bottom surface of the substrate 100. The connection terminals (not shown) may be conductive bumps such as solder balls, pins, lead lines, or the like. The solder balls may be formed of lead (Pb), tin (Sn), an alloy of Pb and Sn, silver (Ag), copper (Cu), aluminium (Al), or the like, by using a soldering device, but are not limited thereto.

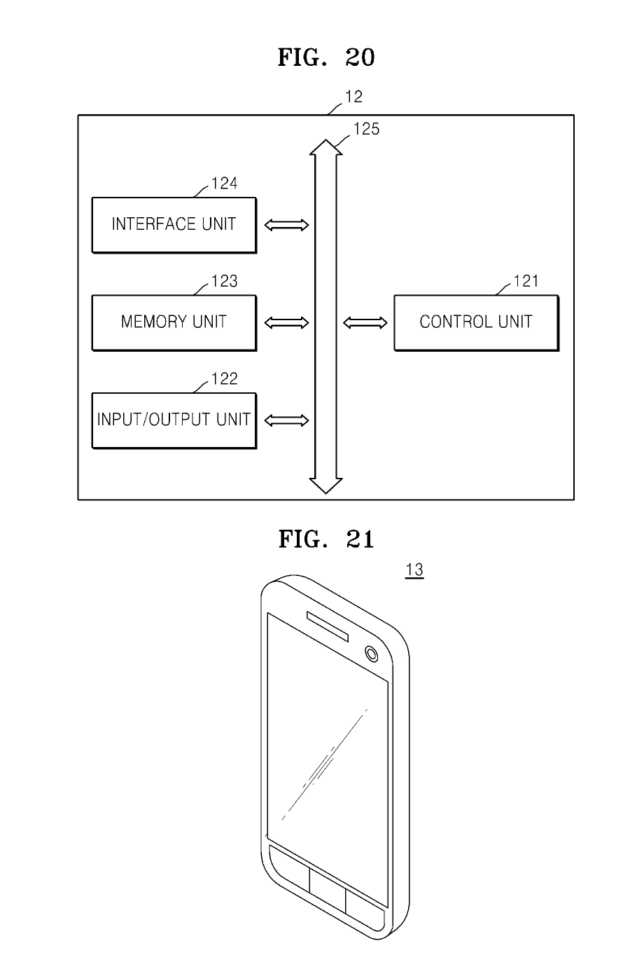

FIG. 20 is a somewhat schematic diagram illustrating a system 12 according to an embodiment of the inventive concept. Referring to FIG. 20, the system 12 may include a control unit 121, an input/output unit 122, a memory unit 123, and an interface unit 124. The system 12 may, for instance, be a mobile system or a system for transmitting or receiving information. The mobile system may be used in a personal digital assistant (PDA), a portable computer, a web tablet, a wireless phone, a mobile phone, a digital music player, or a memory card, for example.

The system 12 may execute a program and may control the system 12. For example, the control unit 121 may be a micro-processor, a digital signal processor, a micro-controller, or the like. The input/output unit 122 may be used to input data of or to output data from the system 12. The system 12 may be connected to an external apparatus such as a personal computer or a network by using the input/output unit 122, and thus, may exchange data with the external apparatus. The input/output unit 122 may be a keypad, a keyboard, or a display.

The memory unit 123 may store codes and/or data for operations of the control unit 121, and/or may store data processed by the control unit 121. The memory unit 123 may include one of the semiconductor packages according to the one or more embodiments of the inventive concept.

The interface unit 124 may be a data transmission path between the system 12 and an external device. The control unit 121, the input/output unit 122, the memory unit 123, and the interface unit 124 may communicate with each other via a bus (not shown). For example, the system 12 may be used in mobile phones, MPEG-1 Audio Layer 3 (MP3) players, navigation devices, portable multimedia players (PMPs), solid state disk (SSDs), or household appliances.

FIG. 21 is a somewhat schematic perspective view illustrating an electronic device to which one of the semiconductor packages according to the one or more embodiments of the inventive concept may be applied. Referring to FIG. 21, the system 12 of FIG. 20 may be applied to a mobile phone 13. The system 12 of FIG. 20 may also be applied, however, to portable notebooks, MP3 players, navigation devices, SSDs, vehicles, household appliances, or other desired device.

While the inventive concept has been particularly shown and described with reference to exemplary embodiments thereof, it will be understood that various changes in form and details may be made therein without departing from the spirit and scope of the following claims.

What is claimed is:

1. A semiconductor package comprising:
a substrate;
first and second pads disposed separate from each other on the substrate; and
a solder resist that exposes a portion of the substrate in a region between the first and second pads while covering a portion of the first and second pads in a region other than the region between the first and second pads.

2. The semiconductor package of claim 1, wherein the solder resist is separated from each of the first and second pads in the region between the first and second pads.

3. The semiconductor package of claim 2, wherein the solder resist is formed in a center of the region between the first and second pads.

4. The semiconductor package of claim 1, wherein the first and second pads are symmetrically disposed about the solder resist formed in the region between the first and second pads.

5. The semiconductor package of claim 1, wherein a length in a y direction of the solder resist formed in the region between the first and second pads is substantially equal to or greater than a length in a y direction of side surfaces of the first and second pads, wherein the side surfaces are not covered by the solder resist.

6. The semiconductor package of claim 1, wherein the solder resist is formed in the region between the first and second pads so as to expose a side surface of each of the first and second pads.

7. The semiconductor package of claim 1, further comprising a passive device mounted on the first and second pads.

8. The semiconductor package of claim 7, further comprising a molding member that fills a space between the passive device and the substrate.

9. A semiconductor package comprising:
a substrate;
first and second pads disposed separate from each other on the substrate;
a device electrically connected to the first and second pads; and
a solder resist formed on the substrate between the first and second pads.

10. The semiconductor package of claim 9, wherein the solder resist is separated from an edge of each of the first and second pads.

11. The semiconductor package of claim 10, wherein the solder resist is formed in a center of the substrate between the first and second pads.

12. The semiconductor package of claim 10, wherein a thickness of the solder resist is substantially equal or greater to a thickness of the first and second pads.

13. The semiconductor package of claim 9, wherein the solder resister further comprises a second resist formed on a portion of each of the first and second pads.

14. The semiconductor package of claim 13, wherein the second register expose a portion of each of the first and second pads so as to be electrically connected to the device.

15. The semiconductor package of claim 9, wherein the device is mounted on the first and second pads.

16. The semiconductor package of claim 15, wherein the device is a passive device.

17. A semiconductor package comprising:
a substrate having a first portion and a second portion;
an active device formed in the first portion;
a first passive device formed in the second portion, the first passive device comprising:
first and second pads disposed separate from each other on the second portion of the substrate; and
a solder resist formed on the substrate between the first and second pads and on a portion of each of the first and second pads;
a molding member covering the active device and the first passive device; and
a connection terminal formed on a bottom surface of the substrate so as to be electrically connected to an external apparatus.

18. The semiconductor package of claim 17, wherein the first portion and the second portion of the substrate are positioned on a top surface of the substrate.

19. The semiconductor package of claim 18, further comprising a second passive device formed on the bottom surface of the substrate, the second passive device comprising:
third and fourth pads disposed separate from each other on the bottom surface of the substrate; and
a second solder resist formed on the substrate between the first and second pads and partially on the third and fourth pads.

20. The semiconductor package of claim 17, wherein the first portion is positioned on a top surface of the substrate and the second portion is positioned on the bottom surface of the substrate.
